(19) United States
(12) Patent Application Publication
(10) Pub. No.: US 2021/0126424 A1
(43) Pub. Date: Apr. 29, 2021

(54) SEMICONDUCTOR LASER DIODE AND METHOD FOR PRODUCING SEMICONDUCTOR LASER DIODE

(71) Applicant: SUMITOMO ELECTRIC INDUSTRIES, LTD., Osaka (JP)

(72) Inventors: Yuki ITO, Osaka-shi (JP); Takuo HIRATANI, Osaka-shi (JP)

(73) Assignee: SUMITOMO ELECTRIC INDUSTRIES, LTD., Osaka (JP)

(21) Appl. No.: 17/032,898

(22) Filed: Sep. 25, 2020

(30) Foreign Application Priority Data
Oct. 24, 2019 (JP) 2019-193434

(51) Int. Cl. H01S 5/026; H01S 5/343; H01S 5/12

(52) U.S. Cl. CPC H01S 5/0265; H01S 5/12; H01S 5/34313

(57) ABSTRACT

A semiconductor laser diode includes a semiconductor substrate, a laser portion that is provided on the semiconductor substrate and has an active layer, and an optical modulation portion that is provided on the semiconductor substrate and has a light absorption layer configured to absorb laser light from the laser portion. In the semiconductor laser diode, the light absorption layer includes a first light absorption layer and a second light absorption layer. The active layer, the first light absorption layer, and the second light absorption layer are arranged in this order in a light guiding direction. The first light absorption layer has a first wavelength obtained by photoluminescence measurement, the second light absorption layer has a second wavelength obtained by photoluminescence measurement, and the second wavelength is longer than the first wavelength.

### CROSS REFERENCE TO RELATED APPLICATIONS

This application claims priority from Japanese Patent Application No. 2019-193434 filed on Oct. 24, 2019, and the entire contents of the Japanese patent application are incorporated herein by reference.

### TECHNICAL FIELD

The present disclosure relates to a semiconductor laser diode and a method for producing a semiconductor laser diode.

### BACKGROUND

Patent Literature 1 discloses a semiconductor laser diode having a laser portion and an optical modulation portion of an electroabsorption type.

[Patent Literature 1] Japanese Unexamined Patent Application Publication No. 2011-155157

[Patent Literature 2] Japanese Unexamined Patent Application Publication No. 2013-51319

### SUMMARY

A semiconductor laser diode according to an aspect of the present disclosure includes a semiconductor substrate, a laser portion that is provided on the semiconductor substrate and has an active layer, and an optical modulation portion that is provided on the semiconductor substrate and has a light absorption layer configured to absorb laser light from the laser portion. In the semiconductor laser diode, the light absorption layer includes a first light absorption layer and a second light absorption layer. The active layer, the first light absorption layer, and the second light absorption layer are arranged in this order in a light guiding direction. The first light absorption layer has a first wavelength obtained by photoluminescence measurement, the second light absorption layer has a second wavelength obtained by photoluminescence measurement, and the second wavelength is longer than the first wavelength.

A method for producing a semiconductor laser diode according to another aspect of the present disclosure is a method for producing of a semiconductor laser diode including a laser portion having an active layer; and an optical modulation portion having a light absorption layer configured to absorb laser light from the laser portion. The method includes a step of forming a first semiconductor layer for the active layer on a main surface of a semiconductor substrate having the main surface including a first region, a second region, and a third region that are arranged in this order in a first direction; a step of forming a first mask pattern for the active layer on a first portion of the first semiconductor layer located on the first region and forming a second mask pattern on a second portion of the first semiconductor layer located on the third region; a step of etching a third portion of the first semiconductor layer located on the second region using the first mask pattern and the second mask pattern; and a step of growing a second semiconductor layer for the light absorption layer on the second region using the first mask pattern and the second mask pattern after etching the third portion of the first semiconductor layer.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 is a perspective view schematically showing a semiconductor laser diode according to an embodiment.

FIG. 2A is a cross-sectional view taken along IIa-IIa line of FIG. 1.

FIG. 2B is a cross-sectional view taken along IIb-IIb line of FIG. 1.

FIG. 2C is a cross-sectional view taken along IIc-IIc line of FIG. 1.

FIG. 3 is a diagram illustrating an example of a profile of a photoluminescence wavelength (PL wavelength) and a light intensity along a light guiding direction.

FIG. 4 is a graph showing an example of the PL wavelength that varies along a light guiding direction.

FIG. 5 is a graph showing an example of the relationship between wavelength and amount of light absorption.

FIG. 6A is a plan view schematically showing a step of a method for producing a semiconductor laser diode according to an embodiment.

FIG. 6B is a cross-sectional view taken along VIb-VIb line of FIG. 6A.

FIG. 7A is a plan view schematically showing a step of a method for producing a semiconductor laser diode according to an embodiment.

FIG. 7B is a cross-sectional view taken along VIIb-VIIb line of FIG. 7A.

FIG. 8A is a plan view schematically showing a step of a method for producing a semiconductor laser diode according to an embodiment.

FIG. 8B is a cross-sectional view taken along VIIIb-VIIIb line of FIG. 8A.

FIG. 9A is a plan view schematically showing a step of a method for producing a semiconductor laser diode according to an embodiment.

FIG. 9B is a cross-sectional view taken along IXb-IXb line of FIG. 9A.

FIG. 10 is a graph showing a profile of PL wavelength along the first direction.

FIG. 11A is a plan view schematically showing a step of a method for producing a semiconductor laser diode according to an embodiment.

FIG. 11B is a cross-sectional view taken along XIb-XIb line of FIG. 11A.

FIG. 12A is a plan view schematically showing a step of a method for producing a semiconductor laser diode according to an embodiment.

FIG. 12B is a cross-sectional view taken along XIIb-XIIb of FIG. 12A.

### DETAILED DESCRIPTION

In the semiconductor laser diode of Patent Literature 1, when no voltage is applied to an optical modulation portion, laser light emitted from a laser portion is incident on an incident end of the optical modulation portion and is emitted from an emitting end of the optical modulation portion through the optical modulation portion to the outside (ON state of laser light). When a voltage is applied to the optical modulation portion, laser light is absorbed by a light absorption layer of the optical modulation portion, so that most of laser light is not emitted to the outside (OFF state of laser light). In the above semiconductor laser diode, the intensity of laser light decreases exponentially from the incident end to the emitting end of the optical modulation portion. Therefore, the intensity of laser light is not sufficiently lowered at the emitting end of the optical modulation portion. That is, it is difficult to increase an extinction ratio which is the ratio of the intensity of laser light in the ON state of laser light to that in the OFF state of laser light.

This disclosure provides a semiconductor laser diode that can increase an extinction ratio of an optical modulation portion and a method for producing the semiconductor laser diode.

### Description of the Embodiments of the Disclosure

A semiconductor laser diode according to an embodiment includes a semiconductor substrate, a laser portion that is provided on the semiconductor substrate and has an active layer, and an optical modulation portion that is provided on the semiconductor substrate and has a light absorption layer configured to absorb laser light from the laser portion. In the semiconductor laser diode, the light absorption layer includes a first light absorption layer and a second light absorption layer. The active layer, the first light absorption layer, and the second light absorption layer are arranged in this order in a light guiding direction. The first light absorption layer has a first wavelength obtained by photoluminescence measurement, the second light absorption layer has a second wavelength obtained by photoluminescence measurement, and the second wavelength is longer than the first wavelength.

According to the semiconductor laser diode, laser light emitted from the laser portion is incident on an incident end of the first light absorption layer and reaches an emitting end of the second light absorption layer through the first light absorption layer and the second light absorption layer. The light absorption layers are configured to absorb laser light when a voltage is applied. In the semiconductor laser diode, the second light absorption layer has a second wavelength longer than the first wavelength. For this reason, the amount of light absorption in the entire light absorption layer is larger than the amount of light absorption when the entire light absorption layer has the first wavelength. Therefore, it is possible to reduce the intensity of laser light at the emitting end of the second light absorption layer. Consequently, the extinction ratio of the optical modulation portion can be increased.

The second wavelength may be monotonically increased from the incident end to the emitting end of the second light absorption layer in the light guiding direction. In this case, it is possible to lower the intensity of laser light at the emitting end of the second light absorption layer.

When the lengths of the first light absorption layer and the second light absorption layer in the light guiding direction are represented by L1 and L2, respectively, the value of L2/(L1+L2) may be 0.05 or more. In this case, it is possible to lower the intensity of laser light at the emitting end of the second light absorption layer.

The emitting end of the second light absorption layer in the light guiding direction may be the emitting end of the semiconductor laser diode. In this case, laser light from the emitting end of the second light absorption layer is emitted directly to the outside.

A method for producing a semiconductor laser diode according to another embodiment is a method for producing a semiconductor laser diode including a laser portion having an active layer; and an optical modulation portion having a light absorption layer configured to absorb laser light from the laser portion. The method includes a step of forming a first semiconductor layer for the active layer on a main surface of a semiconductor substrate having the main surface including a first region, a second region, and a third region that are arranged in this order in a first direction; a step of forming a first mask pattern for the active layer on a first portion of the first semiconductor layer located on the first region and forming a second mask pattern on a second portion of the first semiconductor layer located on the third region; a step of etching a third portion of the first semiconductor layer located on the second region using the first mask pattern and the second mask pattern; and a step of growing a second semiconductor layer for the light absorption layer on the second region using the first mask pattern and the second mask pattern after etching the third portion of the first semiconductor layer.

According to the method for producing a semiconductor laser diode, when growing the second semiconductor layer, the first light absorption layer away from the second mask pattern has a first wavelength obtained by photoluminescence measurement. Further, in the second semiconductor layer, the second light absorption layer close to the second mask pattern has a second wavelength obtained by photoluminescence measurement. The second wavelength is longer than the first wavelength. Thus, the optical modulation portion of the resulting semiconductor laser diode will include a first light absorption layer having a first wavelength and a second light absorption layer having a second wavelength longer than the first wavelength. Therefore, in the obtained semiconductor laser diode, since the second light absorption layer has a second wavelength longer than the first wavelength, the amount of light absorption in the second light absorption layer is larger than that of the light absorption when the entire light absorption layer has the first wavelength. Therefore, it is possible to reduce the intensity of laser light at the emitting end of the second light absorption layer, and thus it is possible to increase the extinction ratio of the optical modulation portion.

### [Details of the Embodiments of the Present Disclosure]

Hereinafter, embodiments according to the present disclosure will be described in detail with reference to the drawings. In the description of the drawings, like or corresponding elements are denoted by like reference numerals and redundant descriptions thereof will be omitted.

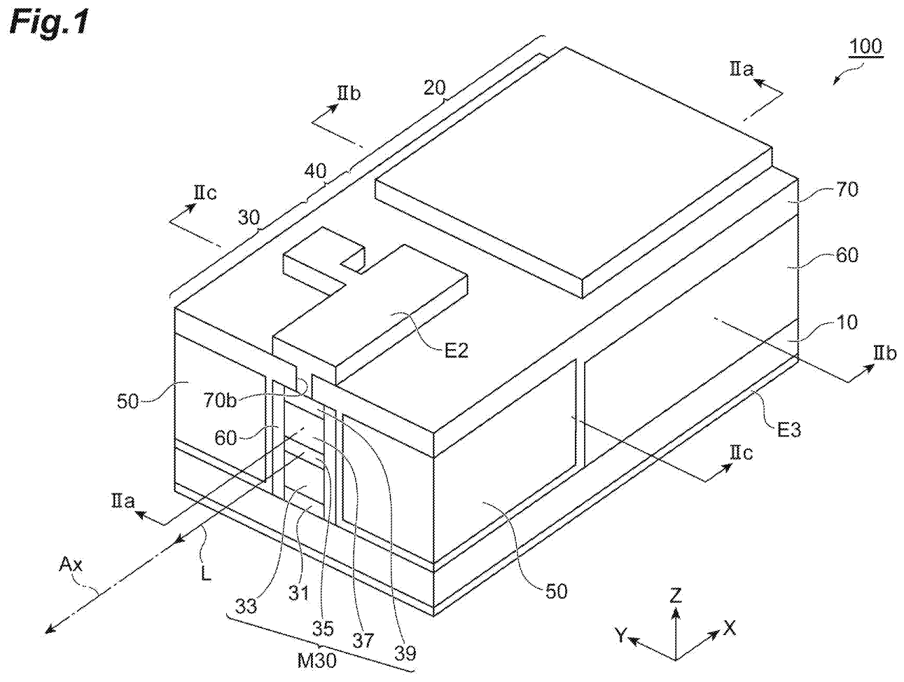

FIG. 1 is a perspective view schematically showing a semiconductor laser diode according to an embodiment. The XYZ

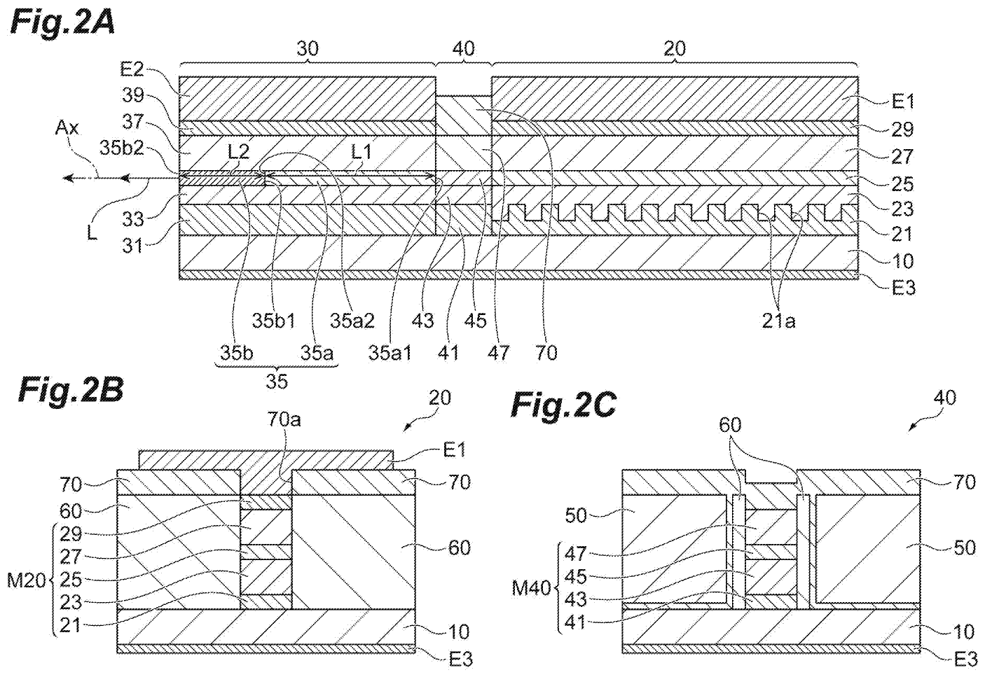

Cartesian coordinate system is shown in FIG. 1. FIG. 2A is a cross-sectional view taken along IIa-IIa line of FIG. 1. FIG. 2B is a cross-sectional view taken along IIb-IIb line of FIG. 1. FIG. 2C is a cross-sectional view taken along IIc-IIc line of FIG. 1. A semiconductor laser diode 100 shown in FIG. 1 includes a semiconductor substrate 10, a laser portion 20 provided on the semiconductor substrate 10, and an optical modulation portion 30 that is provided on the semiconductor substrate 10 and is configured to modulate laser light L from the laser portion 20. The semiconductor substrate 10 extends along the XY plane. The semiconductor laser diode 100 may further comprise a waveguide portion 40 that is provided on the semiconductor substrate 10 and is disposed between the laser portion 20 and the optical modulation portion 30. The laser portion 20, the waveguide portion 40 and the optical modulation portion 30 are arranged in this order along a light guiding direction Ax (X-axis direction) of the semiconductor laser diode 100. Laser light L emitted from the laser portion 20 travels along the light guiding direction Ax, and is emitted to the outside of the semiconductor laser diode 100 through the waveguide portion 40 and the optical modulation portion 30. The length of the semiconductor laser diode 100 along the light guiding direction Ax is, for example, from 400 μm to 800 μm. The width (Y-axis length) of the semiconductor laser diode 100 perpendicular to the light guiding direction Ax is from 200 μm to 300 μm, for example.

The semiconductor substrate 10 is a first-conductivity-type III-V group semiconductor substrate such as an n-InP substrate, for example.

The laser portion 20 may include a diffractive grating layer 21, a lower cladding layer 23, an active layer 25, an upper cladding layer 27, a contact layer 29, and a first electrode E1 that are provided on the semiconductor substrate 10 in this order. The diffractive grating layer 21, the lower cladding layer 23, the active layer 25, the upper cladding layer 27 and the contact layer 29 constitute a semiconductor mesa M20 extending in the light guiding direction Ax. The width of the semiconductor mesa M20 (length in the Y-axis direction) is, for example, from 1 μm to 2 μm. The semiconductor mesa M20 is embedded by a buried semi-insulating semiconductor region 60. An insulating layer 70 is disposed on the buried semi-insulating semiconductor region 60. The first electrode E1 is disposed on the insulating layer 70. The insulating layer 70 has an opening 70a (see FIG. 2B) located on the contact layer 29. In the opening 70a, the first electrode E1 contacts the contact layer 29. The third electrode E3 is provided on the back surface of the semiconductor substrate 10. The length of the laser portion 20 along the light guiding direction Ax is from 300 μm to 600 μm, for example.

The diffractive grating layer 21 is a first-conductivity-type III-V group semiconductor layer such as an n-type GaInAsP layer, for example. The diffractive grating layer 21 has a plurality of grooves 21a arranged along the light guiding direction Ax. Each groove 21a extends in a direction (Y-axis direction) intersecting the light guiding direction Ax. The diffraction grating is formed by the plurality of grooves 21a.

The lower cladding layer 23 is a first-conductivity-type III-V group semiconductor layer such as an n-type InP layer. The lower cladding layer 23 embeds the plurality of grooves 21a in the diffractive grating layer 21.

The active layer 25 has a multi quantum well (MQW) structure including a plurality of well layers and a plurality of barrier layers. In the MQW structure, the well layer and the barrier layer are alternately stacked. The active layer 25 includes GaInAsP-based or AlInGaAs-based III-V group semiconductors, for example. The active layer 25 may generate laser light L depending on a forward bias voltage applied between the first electrode E1 and the third electrode E3. The emission wavelength of laser light L may be 1300 nm or 1550 nm, for example.

The upper cladding layer 27 is a second-conductivity-type III-V group semiconductor layer such as a p-type InP layer or the like. Laser light L is confined in the active layer 25 that is a core layer by the lower cladding layer 23 and the upper cladding layer 27.

The contact layer 29 is a second-conductivity-type III-V group semiconductor layer such as a p-type GaInAs layer or the like.

The buried semi-insulating semiconductor region 60 is a region formed of a semi-insulating InP, for example. The insulating layer 70 is, for example, an inorganic insulating layer such as a SiO₂ layer. The first electrode E1 and the third electrode E3 are metal layers each containing gold.

The optical modulation portion 30 is of electroabsorption type. The optical modulation portion 30 may include a semiconductor layer 31, a lower cladding layer 33, a light absorption layer 35, an upper cladding layer 37, a contact layer 39, and a second electrode E2 that are provided on the semiconductor substrate 10 in this order. The semiconductor layers 31, the lower cladding layer 33, the light absorption layer 35, the upper cladding layer 37, and the contact layer 39 constitute a semiconductor mesa M30 extending to the light guiding direction Ax. The width of the semiconductor mesa M30 (length in the Y-axis direction) is, for example, from 1 μm to 2 μm. As shown in FIG. 1, the buried semi-insulating semiconductor region 60 has a cover layer covering both sides of the mesa M30. The cover layer of the semiconducting mesa M30 and the buried semi-insulating semiconductor region 60 are embedded by a buried insulating resin region 50. The buried insulating resin region 50 is a region formed of a benzocyclobutene (BCB) resin, for example. The insulating layer 70 is interposed between the buried insulating resin region 50 and the buried semi-insulating semiconductor region 60. The insulating layer 70 is also interposed between the buried insulating resin region 50 and the semiconducting substrate 10. The second electrode E2 is disposed on the semiconductor mesa M30 configured to be in contact with the semiconductor mesa M30 through the opening 70b of the insulating layer 70. In the opening 70b, the second electrode E2 contacts with the contact layer 39 of the semiconductor mesa M30. The length of the optical modulation portion 30 along the light guiding direction Ax is from 50 μm to 200 μm, for example.

The semiconductor layer 31, the lower cladding layer 33, the upper cladding layer 37 and the contact layer 39 in the semiconductor mesa M30 contain the same semiconductor materials as the diffractive grating layer 21, the lower cladding layer 23, the upper cladding layer 27 and the contact layer 29 in the semiconductor mesa M20, respectively. The second electrode E2 is a metal layer containing gold.

The light absorption layer 35 has a multi quantum well (MQW) structure including a plurality of well layers and a plurality of barrier layers. In the MQW structure, the well layer and the barrier layer are alternately stacked. The light absorption layer 35 includes GaInAsP-based or AlGaAsP-based III-V group semiconductors, for example. The light absorption layer 35 may absorb and modulate laser light L depending on a voltage applied between the second electrode E2 and the third electrode E3. Specifically, when a voltage of the reverse bias is applied between the second electrode E2 and the third electrode E3 (OFF state of laser light), the light absorption layer 35 absorbs laser light L. If the voltage is not applied between the second electrode E2 and the third electrode E3 (ON state of laser light), the light absorption layer 35 transmits laser light L.

The light absorption layer 35 includes a first light absorption layer 35a and a second light absorption layer 35b. The active layer 25, the first light absorption layer 35a, and the second light absorption layer 35b of the laser portion 20 are arranged in this order along the light guiding direction Ax. The first light absorption layer 35a has an incident end 35a1 and an emitting end 35a2 in the light guiding direction Ax. The second light absorption layer 35b has an incident end 35b1 and an emitting end 35b2 in the light guiding direction Ax. The emitting end 35a2 of the first light absorption layer 35a is connected to the incident end 35b1 of the second light absorption layer 35b. The emitting end 35b2 of the second light absorption layer 35b may be an emitting end of the semiconductor laser diode 100. The emitting end 35b2 of the second light absorption layer 35b may be provided with an antireflection coating.

When the length of the first light absorption layer 35a in the light guiding direction Ax is represented by L1, and the length of the second light absorption layer 35b in the light guiding direction Ax is represented by L2, the value of L2/(L1+L2) may be 0.05 or more, or 0.2 or more. The value of L2/(L1+L2) may be 1.0 or less, or 0.5 or less. The length L2 is from 10 μm to 100 μm, for example. The sum L1+L2 is 50 μm to 200 μm, for example.

The waveguide portion 40 includes a semiconductor layer 41, a lower cladding layer 43, a waveguide layer 45, and an upper cladding layer 47 that are disposed in sequence on the semiconductor substrate 10. The semiconductor layer 41, the lower cladding layer 43, the waveguide layer 45, and the upper cladding layer 47 constitute a semiconductor mesa M40. The semiconductor mesa M40 is located between the semiconductor mesa M20 and the semiconductor mesa M30. The buried semi-insulating semiconductor region 60 has a cover layer covering both sides of the semiconductor mesa M40. The cover layer of the semiconducting mesa M40 and the buried semi-insulating semiconductor region 60 are embedded by the buried insulating resin region 50. The insulating layer 70 is interposed between the buried insulating resin region 50 and the buried semi-insulating semiconductor region 60. The length of the waveguide portion 40 along the light guiding direction Ax is from 20 μm to 150 μm, for example. The waveguide layer 45 is a GaInAsP bulk layer, for example. The semiconductor layer 41, the lower cladding layer 43 and the upper cladding layer 47 in the semiconductor mesa M40 contain the same semiconductor materials as the diffractive grating layer 21, the lower cladding layer 23 and the upper cladding layer 27 in the semiconductor mesa M20, respectively.

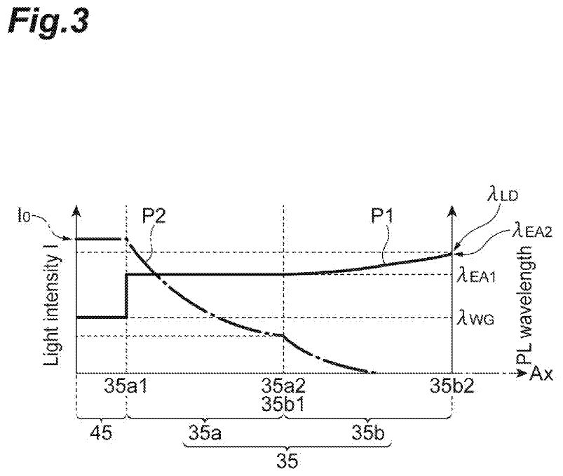

FIG. 3 is a diagram showing an example of a profile of the PL wavelength along the light guiding direction and a profile of the light intensity in a state where a voltage is applied to the optical modulation portion 30 (OFF state of laser light). The horizontal axis indicates the position along the light guiding direction Ax. The vertical axis shows the wavelength (PL wavelength) and the light intensity I obtained by photoluminescence measurement. In FIG. 3, the profile P1 of the PL wavelength obtained by photoluminescence measurement and the profile P2 of the light intensity I of laser light L are shown.

According to the profile P1, the first light absorption layer 35a has a first wavelength λ_{EA1} obtained by photoluminescence measurement. The second light absorption layer 35b has a second wave length λ_{EA2} obtained by photoluminescence measurement. The second wavelength λ_{EA2} is longer than the first wavelength λ_{EA1}. The difference between the second wavelength λ_{EA2} and the first wavelength λ_{EA1} is from 10 nm to 20 nm, for example. The reason why the second wavelength λ_{EA2} is longer than the first wavelength λ_{EA1} is considered to be that the film thicknesses and the compositions (e.g., the composition of GaInAsP-based III-V group semiconductors or AlGaAsP-based III-V group semiconductors) differ between the first light absorption layer 35a and the second light absorption layer 35b. Photoluminescence measurement for the second wavelength λ_{EA2} is performed under the same condition as photoluminescence measurement for the first wavelength λ_{EA1}. Photoluminescence measurement is performed in a state where a portion of the upper cladding layer 37 is formed on the first light absorption layer 35a and the second light absorption layer 35b. The first wavelength λ_{EA1} may be measured at any position of the first light absorption layer 35a along the light guiding direction Ax. In the present embodiment, the first wavelength λ_{EA1} is measured at the emitting end 35a2 of the first light absorption layer 35a. The first wavelength λ_{EA1} is, for example, constant from the incident end 35a1 to the emitting end 35a2 of the first light absorption layer 35a in the light guiding direction Ax. The second wavelength λ_{EA2} may be measured at any position of the second light absorption layer 35b along the light guiding direction Ax. In the present embodiment, the second wavelength λ_{EA2} is measured at the emitting end 35b2 of the second light absorption layer 35b. For example, the second wavelength λ_{EA2} is monotonically increasing from the incident end 35b1 of the second light absorption layer 35b to the emitting end 35b2 in the light guiding direction Ax. The reason why the second wavelength λ_{EA2} changes depending on the position in the light guiding direction Ax is considered to be that the thickness and the composition of the second light absorption layer 35b (e.g., the composition of GaInAsP-based III-V group semiconductors or AlGaInAs-based III-V group semiconductors) change depending on the position in the light guiding direction Ax. In the present embodiment, the waveguide layer 45 has a wavelength λ_{WG} smaller than the first wavelength λ_{EA1}. The wavelength λ_{WG} is constant over the length of the waveguide layers 45 in the light guiding direction Ax, for example. In the present embodiment, the active layer 25 has a wavelength λ_{LD} longer than the second wavelength λ_{EA2}. The wave length λ_{LD} is constant over the length of the active layer 25 in the light guiding direction Ax, for example.

According to the profile P2, in the present embodiment, the light intensity I of laser light L is I₀ at the interface between the active layer 25 and the waveguide layer 45. The waveguide layer 45 does not absorb laser light L. When a voltage is applied to the optical modulation portion 30, the light intensity I decreases exponentially from the incident end 35a1 to the emitting end 35a2 in the first light absorption layer 35a. When the optical absorption coefficient of the first light absorption layer 35a is α₁ and the position along the light guiding direction Ax is x, the light intensity I is proportional to exp (−α₁x). Also in the second light absorption layer 35b, the light intensity I is exponentially reduced from the incident end 35b1 to the emitting end 35b2. When the optical absorption coefficient of the second light absorption layer 35b is α₂ and the position in light guiding direction Ax is x, the light intensity I is proportional to exp (−α₂x). However, the optical absorption coefficient α₂ is a function of the position x. The optical absorption coefficient α₂ is greater than the optical absorption coefficient α₁. Since the second light absorption layer 35b has the second wavelength λ_{EA2} longer than the first wavelength λ_{EA1}, the light intensity I in the OFF state of laser light in the second light absorption layer 35b is further reduced. This makes it possible to increase the extinction ratio of the optical modulation portion 30.

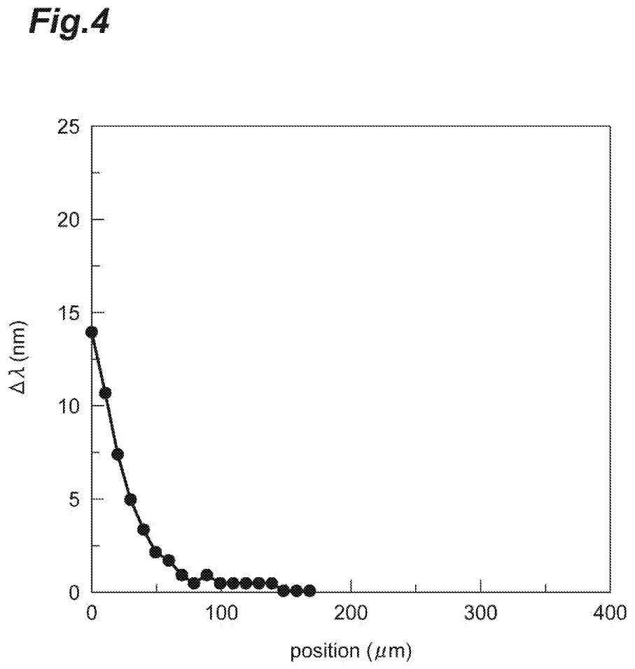

FIG. 4 is a graph showing an example of the PL wavelength that varies along the light guiding direction Ax. The horizontal axis indicates the position along the light guiding direction Ax. The position zero corresponds to the position of the emitting end 35b2 of the second light absorption layer 35b. The larger the value on the horizontal axis, the farther away from the emitting end 35b2 in the light absorption layer 35. The vertical axis represents a difference αλ between the second wavelength λ_{EA2} and the first wavelength λ_{EA1} obtained by photoluminescence measurement. As shown in FIG. 4, in the present embodiment, the difference between the second wavelength λ_{EA2} and the first wavelength λ_{EA1} is about 15 nm. The length L2 of the second light absorption layer 35b in the light guiding direction Ax is about 80 μm to about 90 μm. In the present embodiment, the first wavelength λ_{EA1} of the first light absorption layer 35a is 1250 nm, and the wavelength λ_{LD} of the active layer 25 is 1300 nm. Photoluminescence measurement of the present embodiment is performed as follows. The samples subjected to photoluminescence measurement are obtained by butt-joint growing, on the substrate 10, the MQW structure of the light absorption layer 35 and a part of the upper cladding layer 37. The thickness of the upper cladding layer 37 in these samples is from 100 nm to 200 nm. The total thickness of the butt-joint grown layers is about 400 nm. The position zero on the horizontal axis of FIG. 4 corresponds to the position of the edge of the mask used for butt-joint growth. Photoluminescence measurement is performed by irradiating the surface of the sample with an excitation laser. In the measurement, the wavelength of the excitation laser is 532 nm, the power of the excitation laser is 1.5 mW, the irradiation spot diameter of the excitation laser is 10 μm, and the irradiation time is 0.02 seconds. An InGaAs near-infrared detector is used for detecting photoluminescence light.

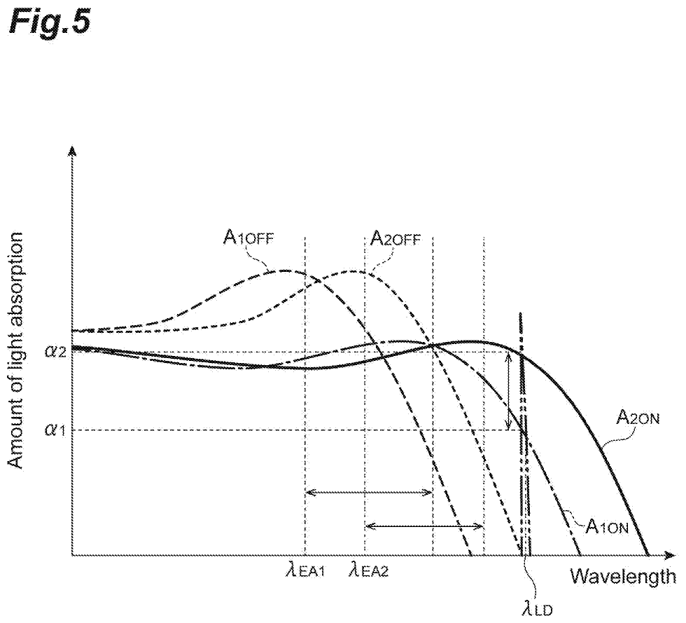

FIG. 5 is a graph showing an example of the relationship between wavelength and amount of light absorption. The horizontal axis indicates the wavelength. The vertical axis represents the amount of light absorption. However, the vertical axis of the peaks in the wavelength λ_{LD} indicates light intensity. FIG. 5 shows a light absorption spectrum A_{1ON} of the first light absorption layer 35a and a light absorption spectrum A_{2ON} of the second light absorption layer 35b in a state in which a voltage is applied to the optical modulation portion 30 using the second electrode E2 (ON state of voltage). FIG. 5 also shows a light absorption spectrum A_{1OFF} of the first light absorption layer 35a and a light absorption spectrum A_{2OFF} of the second light absorption layer 35b in a state in which no voltage is applied to the optical modulation portion 30 (OFF state of voltage). The peak wavelengths of the optical absorption spectra A_{1OFF} and A_{2OFF} in the OFF state of voltage are located in the vicinity of the first wavelength λ_{EA1} and the second wavelength 2_{EA2}, respectively. In the OFF state of voltage, since there is no overlap with the optical spectra A_{1OFF} and A_{2OFF}, laser light L transmits through the optical modulation portion 30 to be emitted. On the other hand, since the wavelength λ_{LD} overlaps with the optical absorption spectra A_{1ON} and A_{2ON} in the ON state of voltage, laser light L is absorbed by the optical modulation portion 30. As a result, laser light L is not emitted. In the ON state of voltage, the optical absorption spectrum A_{2ON} is larger than the optical absorption spectrum A_{1ON} at the wavelength λ_{LD}. This indicates that the amount of light absorption in the second light absorption layer 35b having the light absorption coefficient α₂ larger than the light absorption coefficient α₁ is larger than that in the first light absorption layer 35a having the light absorption coefficient α₁. The extinction ratio of the optical modulation portion 30 is greater as the difference between the optical absorption coefficients α₁ and α₂ is greater.

According to the semiconductor laser diode 100, laser light L emitted from the laser portion 20 is incident on the incident end 35a1 of the first light absorption layer 35a, and reaches the emitting end 35b2 of the second light absorption layer 35b through the first light absorption layer 35a and the second light absorption layer 35b. As shown in FIGS. 3 and 5, in the semiconductor laser diode 100, the second light absorption layer 35b has a second wavelength λ_{EA2} longer than the first wavelength λ_{EA1}. Therefore, the amount of light absorption in the light absorption layer 35 is larger than the amount of light absorption when the entire light absorption layer has the first wavelength λ_{EA1}. Therefore, the intensity of laser light L at the emitting end 35b2 of the second light absorption layer 35b is reduced. That is, the amount of light absorption at the emitting end 35b2 of the second light absorption layer 35b is increased. Therefore, it is possible to improve the extinction ratio of the semiconductor laser diode 100. In one example, the extinction ratio is improved by about 1 dB to 2 dB. Alternatively, it is possible to shorten the length of the optical modulation portion 30 along the light guiding direction Ax while maintaining the extinction ratio of the semiconductor laser diode 100. In this case, it is possible to reduce the device capacitance of the optical modulation portion 30, and thus it is possible to realize the optical modulation portion 30 with a higher speed.

When the second wavelength 2_{EA2} monotonously increases from the incident end 35b1 of the second light absorption layer 35b to the emitting end 35b2 in the light guiding direction Ax, the intensity of laser light L at the emitting end 35b2 of the second light absorption layer 35b can be made lower. Usually, since laser light is exponentially reduced in the light absorption layer, it is difficult to bring the intensity of laser light L close to zero at the emitting end of the light absorption layer. On the other hand, when the second wavelength λ_{EA2} monotonously increases from the incident end 35b1 of the second light absorption layer 35b to the emitting end 35b2 in the light guiding direction Ax, the intensity of laser light L at the emitting end 35b2 of the second light absorption layer 35b can be made close to zero.

When the length of the first light absorption layer 35a in the light guiding direction Ax is represented by L1, and the length of the second light absorption layer 35b in the light guiding direction Ax is represented by L2, the value of L2/(L1+L2) may be 0.05 or more. In this instance, the intensity of laser light L at the emitting end 35b2 of the second light absorption layer 35b can be further reduced.

When the emitting end 35b2 of the second light absorption layer 35b is the emitting end of the semiconductor laser diode 100, laser light L is emitted from the emitting end 35b2 of the second light absorption layer 35b directly to the outside.

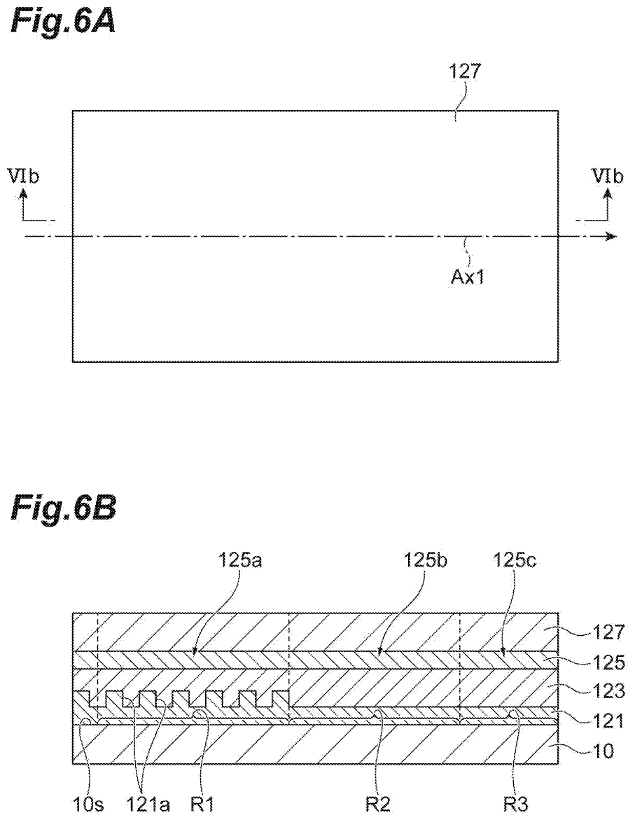

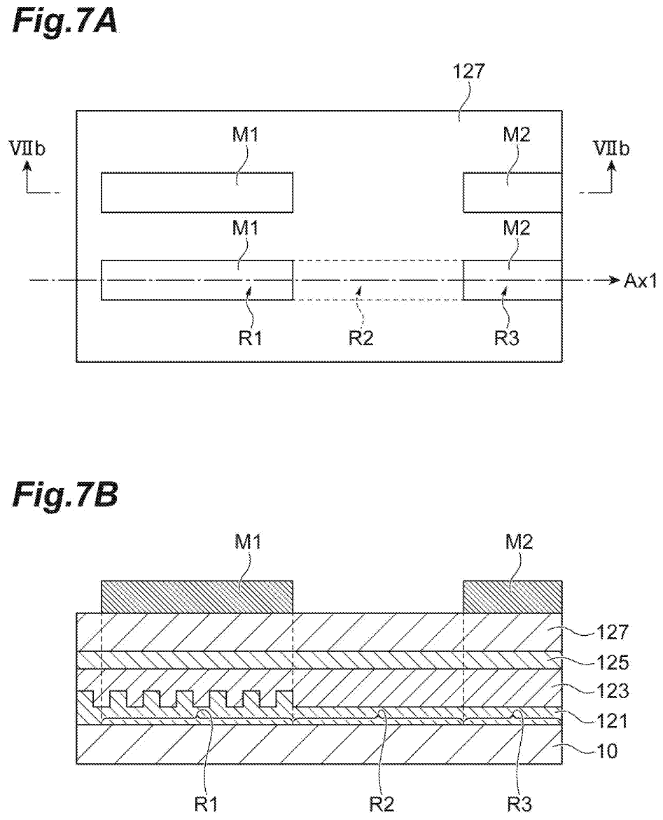

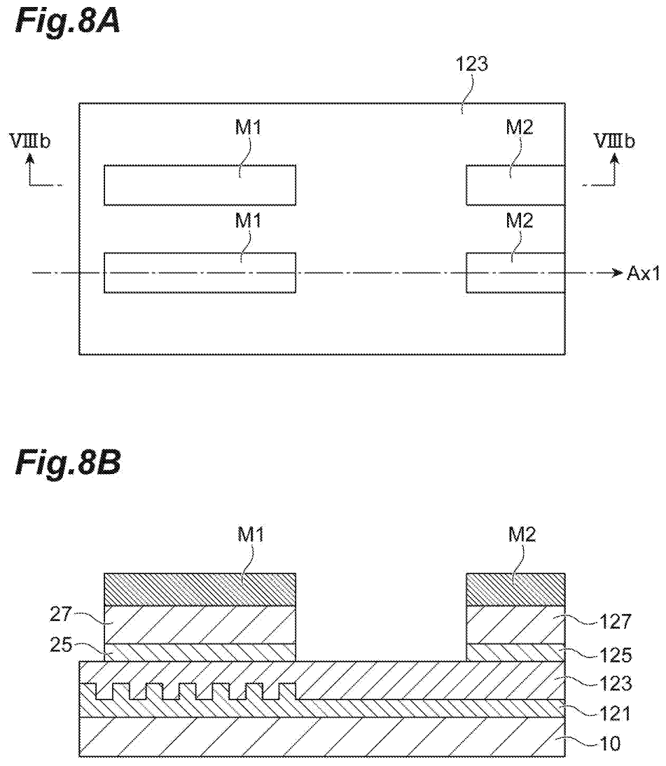

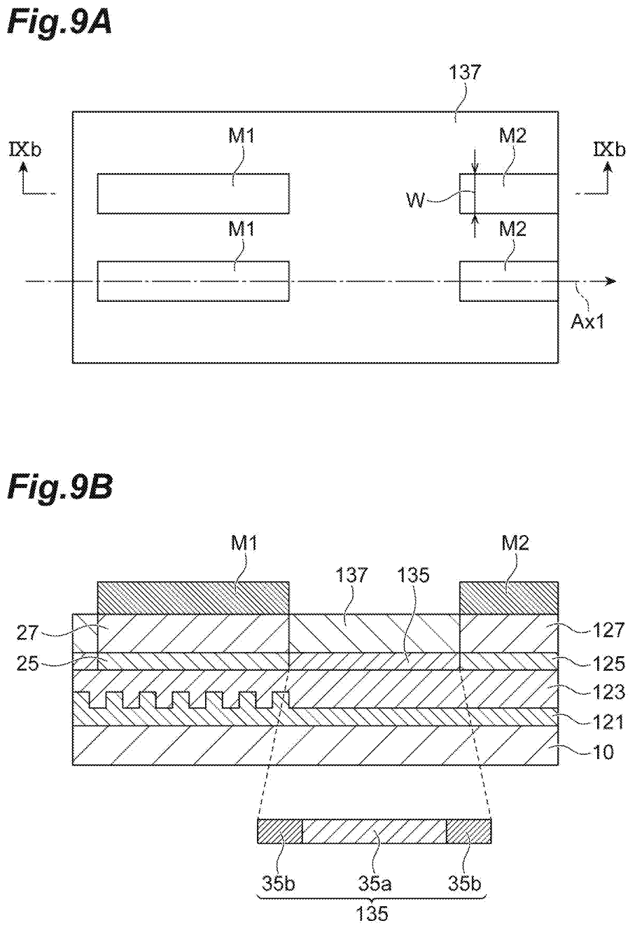

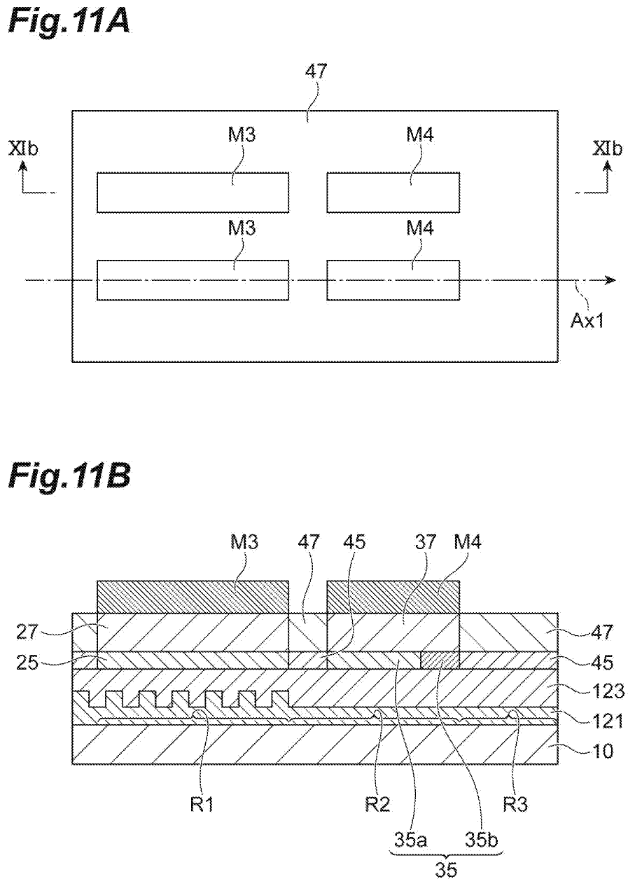

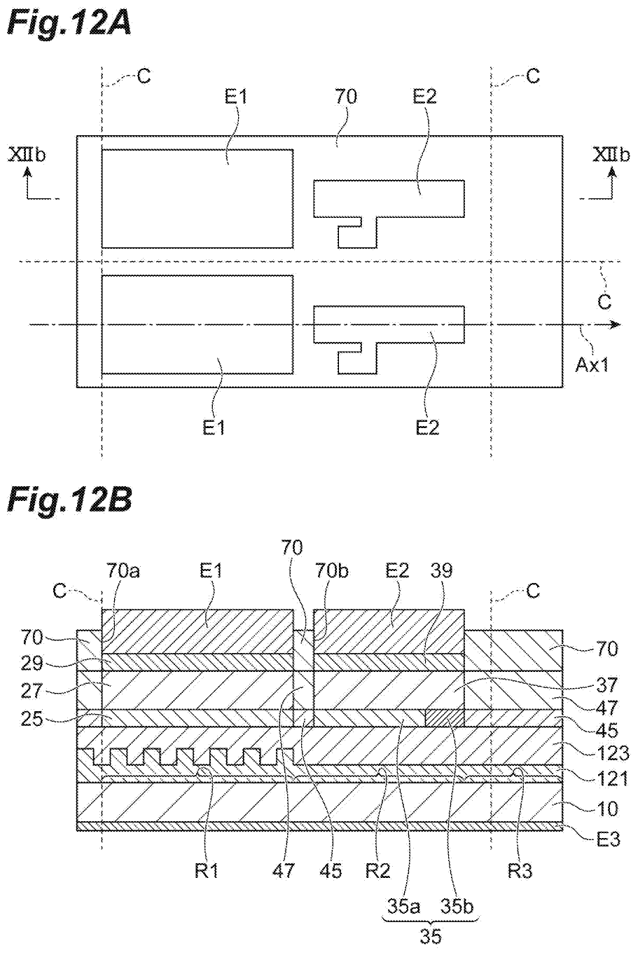

The semiconductor laser diode 100 described above is produced by the following methods, for example. FIGS. 6A, 7A, 8A, 9A, 11A and 12A are plan views schematically showing steps in a method for producing a semiconductor laser diode according to an embodiment. FIG. 6B is a cross-sectional view taken along VIb-VIb line of FIG. 6A. FIG. 7B is a cross-sectional view taken along VIIb-VIIb line of FIG. 7A. FIG. 8B is a cross-sectional view taken along VIIIb-VIIIb line of FIG. 8A. FIG. 9B is a cross-sectional view taken along IXb-IXb line of FIG. 9A. FIG. 11B is a cross-sectional view taken along XIb-XIb line of FIG. 11A. FIG. 12B is a cross-sectional view taken along XIIb-XIIb of FIG. 12A.

(Step of Forming a First Semiconductor Layer)

First, as shown in FIGS. 6A and 6B, a semiconductor substrate 10 has a main surface 10s including a first region R1, a second region R2 and a third region R3 that are arranged in this order in a first direction Ax1 as a light guiding direction Ax. A first semiconductor layer 125 for an active layer 25 is formed on the main surface 10s of the semiconductor substrate 10. The first semiconductor layer 125 has a first portion 125a, a third portion 125b, and a second portion 125c that are located on the first region R1, the second region R2, and the third region R3, respectively.

Prior to forming the first semiconductor layer 125, a semiconductor layer 121 for a diffractive grating layer 21 and a semiconductor layer 123 for a lower cladding layer 23 are formed on the main surface 10s in this order. For example, grooves 121a serving as grooves 21a of the diffractive grating layer 21 are formed on the semiconductor layer 121 by photolithography, dry etching, and the like. The grooves 121a are located on the first region R1. After forming the first semiconductor layer 125, a semiconductor layer 127 for an upper cladding layer 27 is formed. The semiconductor layer 121, the semiconductor layer 123, the first semiconductor layer 125, and the semiconductor layer 127 are grown by metal organic chemical vapor phase epitaxy (MOVPE) or the like. A buffer layer having the same composition as that of the semiconductor substrate 10 may be grown between the semiconductor layer 121 for the diffractive grating layer 21 and the main surface 10s.

(Step of Forming a First Mask Pattern and a Second Mask Pattern)

Next, as shown in FIGS. 7A and 7B, a first mask pattern M1 for the active layer 25 is formed on the first portion 125a of the first semiconductor layer 125. A second mask pattern M2 is formed on the second portion 125c of the first semiconductor layer 125. The first mask pattern M1 and the second mask pattern M2 are inorganic layers such as SiO₂ layers or the like. The first mask pattern M1 and the second mask pattern M2 are formed by photolithography, for example. The distance between the first mask pattern M1 and the second mask pattern M2 along the first direction Ax1 is from 70 μm to 350 μm, for example. The length of the first mask pattern M1 along the first direction Ax1 is from 300 μm to 600 μm, for example. The width of the first mask pattern M1 perpendicular to the first direction Ax1 is from 10 μm to 20 μm, for example.

(Step of Etching)

Next, as shown in FIGS. 8A and 8B, the third portion 125b of the first semiconductor layer 125 is etched by, for example, dry etching using the first mask pattern M1 and the second mask pattern M2. Prior to etching the third portion 125b, a portion located on the third portion 125b of the semiconductor layer 127 is also etched.

(Step of Growing A Second Semiconductor Layer)

Next, as shown in FIGS. 9A and 9B, the first mask pattern M1 and the second mask pattern M2 are used to butt-joint grow the second semiconductor layer 135 for the light absorption layer 35 on the second region R2. After butt-joint growth of the second semiconductor layer 135, the semiconductor layer 137 for the upper cladding layer 37 is grown. The second semiconductor layer 135 and the semiconductor layer 137 are grown by, for example, metal organic chemical vapor phase epitaxy (MOVPE) or the like, respectively. A butt-joint interface is formed between the first semiconductor layer 125 and the second semiconductor layer 135. In the vicinity of the butt-joint interface, the PL wavelength is longer due to the effect of selective growth using a mask. Therefore, the second semiconductor layer 135 has the first light absorption layer 35a, and the second light absorption layer 35b provided in the vicinity of the butt-joint interface. The second light absorption layer 35b is formed in the vicinity of each of the first mask pattern M1 and the second mask pattern M2.

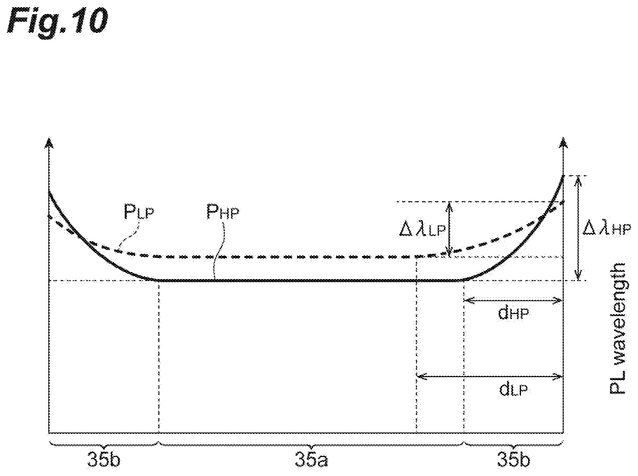

FIG. 10 is a graph showing a profile of the PL wavelength along the first direction. The horizontal axis indicates the position along the first directional Ax1 in the second semiconductor layer 135. The vertical axis shows the PL wavelength. FIG. 10 shows a profile P_{HP} of the PL wavelength when the second semiconductor layer 135 is grown at a high pressure, and a profile P_{LP} of the PL wavelength when the second semiconductor layer 135 is grown at a low pressure.

As shown in FIG. 10, in the profile P_{HP}, the difference between the PL wavelength obtained in the first light absorption layer 35a and the PL wavelength obtained in the second light absorption layer 35b is Δλ_{HP}. In the profile P_{LP}, the difference between the PL wavelength obtained in the first light absorption layer 35a and the PL wavelength obtained in the second light absorption layer 35b is Δλ_{LP}. The Δλ_{LP} is less than the Δλ_{HP}. The Δλ_{HP} and the Δλ_{LP} correspond to the Δλ in FIG. 4. Further, in the profile P_{HP}, the length of the second light absorption layer 35b along the first direction Ax1 is d_{HP}. In the profile P_{LP}, the length of the second light absorption layer 35b along the first directional Ax1 is d_{LP}. The length d_{LP} is longer than the length d_{HP}. The lengths d_{H}p and d_{LP} correspond to the length L2 of the second light absorption layer 35b shown in FIG. 2A. Therefore, the difference between the PL wavelengths obtained in the first light absorption layer 35a and the second light absorption layer 35b, and the length of the second light absorption layer 35b along the first directional Ax1 can be adjusted by adjusting the pressures at which the second semiconductor layer 135 is grown. Further, by increasing the width W of the second mask pattern M2, the difference between the PL wavelengths obtained in the first light absorption layer 35a and the second light absorption layer 35b can be increased. The width W is the length of the second mask pattern M2 in the direction perpendicular to the first direction Ax1 (see FIG. 9A). Therefore, by adjusting the width W of the second mask pattern M2, the difference between the PL wavelengths obtained in the first light absorption layer 35a and the second light absorption layer 35b can be adjusted.

(Step of Forming a Waveguide Layer)

Next, the first mask pattern M1 and the second mask pattern M2 are removed to form a third mask pattern M3 and a fourth mask pattern M4, as shown in FIGS. 11A and 11B. The third mask pattern M3 and the fourth mask pattern M4 are inorganic layers such as SiO₂ layers or the like. The third mask pattern M3 and the fourth mask pattern M4 are formed by photolithography, for example. The third mask pattern M3 is formed on the first region R1 in the same manner as the first mask pattern M1. The fourth mask pattern M4 is formed on a part of the second region R2. One end of the fourth mask pattern M4 (the end farther from the third mask pattern M3 in the first direction Ax1) is located at the boundary between the second region R2 and the third region R3, for example. The distance between the third mask pattern M3 and the other end of the fourth mask pattern M4 (the end closer to the third mask pattern M3 in the first direction Ax1) corresponds to the distance in the first direction Ax1 of the second light absorption layer 35b located between the first light absorption layer 35a and the active layer 25. The position of one end of the fourth mask pattern M4 may be located inside the second region R2. When the position of the one end of the fourth mask pattern M4 is located inside the second region R2, the longest PL wavelength (second wavelength λ_{EA2}) obtained by the second light absorption layer 35b becomes shorter. By accurately controlling the position of the fourth mask pattern M4, the second wavelength λ_{EA2} can be accurately adjusted.

The second semiconductor layer 135 and the semiconductor layer 137 are etched using the third mask pattern M3 and the fourth mask pattern M4. The second light absorption layer 35b located between the third mask pattern M3 and the fourth mask pattern M4 is etched. The second portion 125c of the first semiconductor layer 125 and the semiconductor layer 127 located thereon are also etched.

Next, the waveguide layers 45 and the upper cladding layer 47 are grown using the third mask pattern M3 and the fourth mask pattern M4.

(Step of Forming a Contact Layer)

Next, the third mask pattern M3 and the fourth mask pattern M4 are removed to form a contact layer for a contact layer 29 and a contact layer 39, as shown in FIGS. 12A and 12B.

(Step of Forming a Semiconductor Mesa)

Next, as shown in FIGS. 1, 2B and 2C, the semiconductor mesas M20, M30 and M40 are formed by dry etching using stripe-shaped masks extending along the first directional Ax1, for example.

(Step of Forming a Buried Semi-Insulating Semiconductor Region)

The stripe-shaped mask is then used to grow a buried semi-insulating semiconductor region for the buried semi-insulating semiconductor region 60. As a result, the semiconductor mesas M20, M30 and M40 are buried with the buried semi-insulating semiconductor region. After the stripe-shaped mask is removed, another mask is used for etching the buried semi-insulating semiconductor region. Another mask has stripe-shaped portions covering the top surfaces of the semiconductor mesas M30 and M40, and another portion located on the first region R1. Consequently, the buried semi-insulating semiconductor region 60 is formed.

(Step of Forming a Buried Insulating Resin Region)

After removing another mask, using a CVD method or the like, a first insulating layer to be part of the insulating layer 70 is formed on the entire surface. Thereafter, a resin for a buried insulating resin region 50 is applied to the first insulating layer and cured. As a result, the semiconductor mesas M30 and M40 are filled with the resin. Subsequently, the first insulating layer is exposed by etching back the resin. As a result, the buried insulating resin region 50 is formed.

(Step for Forming a First Electrode, a Second Electrode and a Third Electrode)

Next, on the upper cladding layer 47 constituting a part of the semiconductor mesa M40, by photolithography and etching, an opening is formed in the first insulating layer, and an unwanted part of the contact layer is removed from the first insulating layer. Thus, the contact layer 29 and the contact layer 39 are electrically separated. Thereafter, a second insulating layer serving as a part of the insulating layer 70 is formed. Consequently, as shown in FIG. 12B, the insulating layer 70 instead of the contact layer is located on the upper cladding layer 47.

Next, openings 70a and 70b are formed in the insulating layer 70 to form a first electrode E1 and a second electrode E2 in the openings 70a and 70b, respectively. Furthermore, a third electrode E3 is formed on the back surface of the semiconductor substrate 10.

(Step of Cutting a Semiconductor Substrate)

Next, as shown in FIGS. 12A and 12B, the semiconductor substrate 10 is cut along the cutting line C by cleavage, dicing or the like. This produces a semiconductor laser diode 100 shown in FIG. 1. The cutting line C passes through the second region R2 or the third region R3. In FIGS. 12A and 12B, the cutting line C passes through the third region R3. The waveguide layer 45 of the third region R3 does not absorb laser light L. When the cutting line C passes through the third region R3, even if the position of the cutting line C varies in the production, the intensity of laser light emitted from the semiconductor laser diode 100 does not vary. The cutting line C may be shifted toward the first direction Ax1 so as to cut the second light absorption layer 35b. By changing the position of the cutting line C in the first direction Ax1, the second wavelength λ_{EA2} in the emitting end 35b2 of the second light absorption layer 35b can be adjusted. In this case, cutting the semiconductor substrate is facilitated when shortening the length of the second electrode E2 in the first directional Ax1 so that the second electrode E2 does not overlap with the cutting line C.

According to the above method for producing a semiconductor laser diode 100, when the second semiconductor layer 135 is grown, the first light absorption layer 35a separated from the first mask pattern M1 and the second mask pattern M2 has a first wavelength λ_{EA1} obtained by photoluminescence measurement. The second light absorption layer 35b near the first mask pattern M1 or the second mask pattern M2 in the second semiconductor layer 135 has a second wavelength λ_{EA2} obtained by photoluminescence measurement. The second wavelength λ_{EA2} is longer than the first wavelength λ_{EA1}. Thus, the optical modulation portion 30 of the resulting semiconductor laser diode 100 includes the first light absorption layer 35a having the first wavelength λ_{EA1} and the second light absorption layer 35b having a second wavelength λ_{EA2} greater than the first wavelength λ_{EA1}.

The embodiments of the present disclosure have been described above. However, the embodiments of the present disclosure disclosed above are only illustrative, and the scope of the present invention is not limited to the specific embodiments of the disclosure. It is to be understood that the scope of the present invention is defined in the appended claims and includes equivalence of the description of the claims and all changes within the scope of the claims.

What is claimed is:

1. A semiconductor laser diode comprising:
a semiconductor substrate,
a laser portion that is provided on the semiconductor substrate and has an active layer, and
an optical modulation portion that is provided on the semiconductor substrate and has a light absorption layer configured to absorb laser light from the laser portion,
wherein the light absorption layer includes a first light absorption layer and a second light absorption layer;
the active layer, the first light absorption layer, and the second light absorption layer are arranged in this order in a light guiding direction;
the first light absorption layer has a first wavelength obtained by photoluminescence measurement;
the second light absorption layer has a second wavelength obtained by photoluminescence measurement; and
the second wavelength is longer than the first wavelength.

2. The semiconductor laser diode according to claim 1, wherein the second wavelength monotonically increases from an incident end to an emitting end of the second light absorption layer in the light guiding direction.

3. The semiconductor laser diode according to claim 1, wherein a value of L2/(L1+L2) is 0.05 or more, where L1 represents a length of the first light absorption layer in the light guiding direction and L2 represents a length of the second light absorption layer in the light guiding direction.

4. The semiconductor laser diode according to claim 1, wherein an emitting end of the second light absorption layer in the light guiding direction is an emitting end of the semiconductor laser diode.

5. The semiconductor laser diode according to claim 1, wherein the second wavelength is measured at an emitting end of the second light absorption layer, wherein a difference between the second wavelength and the first wavelength is from 10 nm to 20 nm.

6. The semiconductor laser diode according to claim 1, wherein film thicknesses differ between the first light absorption layer and the second light absorption layer.

7. The semiconductor laser diode according to claim 1, wherein compositions differ between the first light absorption layer and the second light absorption layer.

8. The semiconductor laser diode according to claim 1, wherein a value of L2/(L1+L2) is 0.5 or less, where L1 represents a length of the first light absorption layer in the light guiding direction and L2 represents a length of the second light absorption layer in the light guiding direction.

9. The semiconductor laser diode according to claim 1, wherein a length of the second light absorption layer in the light guiding direction is from 10 μm to 100 μm.

10. A method for producing a semiconductor laser diode including a laser portion having an active layer, and an optical modulation portion having a light absorption layer configured to absorb laser light from the laser portion, the method comprising:
forming a first semiconductor layer for the active layer on a main surface of a semiconductor substrate having the main surface including a first region, a second region, and a third region that are arranged in this order in a first direction;
forming a first mask pattern for the active layer on a first portion of the first semiconductor layer located on the first region and a second mask pattern on a second portion of the first semiconductor layer located on the third region;
etching a third portion of the first semiconductor layer located on the second region using the first mask pattern and the second mask pattern; and
growing a second semiconductor layer for the light absorption layer on the second region using the first mask pattern and the second mask pattern after etching the third portion of the first semiconductor layer.
